(19) United States
(12) Patent Application Publication
(10) Pub. No.: US 2013/0114189 A1
(43) Pub. Date: May 9, 2013

(54) FIXING STRUCTURE AND ELECTRONIC DEVICE APPLYING THE SAME

(71) Applicant: Yun-Tang LIN, Taipei (TW)

(72) Inventor: Yun-Tang LIN, Taipei (TW)

(73) Assignee: INVENTEC CORPORATION, Taipei (TW)

(21) Appl. No.: 13/329,567

(22) Filed: Dec. 19, 2011

(30) Foreign Application Priority Data
Nov. 4, 2011 (TW) 100140393

(51) Int. Cl. H05K 5/00; F16B 2/10; F16L 3/08; F16M 13/02

(52) U.S. Cl. 361/679.01; 248/231.51; 248/74.1

(57) ABSTRACT

A fixing structure is disposed on a surface of a case. An opening is disposed on the surface of the case. The fixing structure comprises a suspension arm and a hook portion. The suspension arm is extended from the surface of the case. The suspension arm has an engaging end and a suspending end. The engaging end is connected to the surface of the case. The suspending end is suspended at the opening. The hook portion is extended from the suspending end and reaches inside the opening. The disclosure further discloses an electronic device applying the fixing structure.

### CROSS-REFERENCE TO RELATED APPLICATIONS

This non-provisional application claims priority under 35 U.S.C. §119(a) on Patent Application No(s). 100140393 filed in Taiwan, R.O.C. on Nov. 4, 2011, the entire contents of which are hereby incorporated by reference.

### BACKGROUND

1. Technical Field

The present disclosure relates to a fixing structure and an electronic device applying fixing structure and more particularly to a fixing structure for arranging wires.

2. Related Art

Disposition of circuits in existing electronic devices are getting more complicated. Therefore, wires are often used for electrical connections between circuit boards in electronic devices. However, as the number of wires increases, of electronic devices becomes even more difficult because the assembling is hindered by the large number of scattered and unorganized wires. For instance, in some assembling procedures, the wires may get broken by the case because of unorganized and scattered arrangement of the wires. Therefore, tapes are often used to fix the wires. However, besides that the material costs will be increased by using tapes for fixation, more procedures are also required in an assembling process; furthermore, after long periods of using the electronic devices, the tapes will loss their stickiness or adhesive chemicals on the tapes may exude. When the electronic devices are required to be opened for maintenance, the wires may be found scattered which makes it difficult for maintenance. As a result, new tapes are needed for fixing the wires again, which is another expense in the material costs. Furthermore, the abovementioned procedures in an assembling process of electronic devices are often complicated; thus not only that the process will be delayed, labor hours are also increased.

### SUMMARY

A fixing structure provided by the disclosure is disposed on a surface of a case. An opening is disposed on the surface of the case. The fixing structure comprises a suspension arm and a hook portion. The suspension arm is extended from the surface of the case. The suspension arm has an engaging end and a suspending end. The engaging end is connected to the surface of the case. The suspending end is suspended at the opening. The hook portion is extended from the suspending end and reaches inside the opening.

An electronic device provided by the disclosure comprises a case, a wire and a fixing structure. The case has a surface, and an opening is disposed on the surface. The wire is disposed on the surface. The fixing structure is disposed on the surface and is adjacent to the opening. The fixing structure comprises a suspension arm and a hook portion. The suspension arm is extended from the surface, and it has an engaging end and a suspending end. The engaging end is connected to the surface. The suspending end is suspended at the opening. The hook portion is extended from the suspending end and reaches inside the opening. The wire passes through between the case and the suspension arm.

The present invention will become more fully understood by reference to the following detailed description thereof when read in conjunction with the attached drawings.

### BRIEF DESCRIPTION OF THE DRAWINGS

The present disclosure will become more fully understood from the detailed description given herein below for illustration only, and thus are not limitative of the present disclosure, and wherein:

FIG. 1 is a perspective view of an electronic device of an embodiment according to the disclosure;

FIG. 2 is a front cross-sectional view of a fixing structure in FIG. 1 along a line 2-2;

FIG. 3 is a front cross-sectional view of a fixing structure of an embodiment according to the disclosure being installed with a wire;

FIG. 4 is a side cross-sectional view of a fixing structure in FIG. 1 along a line 4-4 installed with a wire; and

FIG. 5 is a front cross-sectional view of a fixing structure of an embodiment according to the disclosure with a wire being removed.

### DETAILED DESCRIPTION

In view of the abovementioned problems, the disclosure provides a fixing structure and an electronic device applying the fixing structure, a problem of costs for fixing wires can therefore be solved by disposing the fixing structure on a case.

The detailed characteristics and advantages of the disclosure are described in the following embodiments in details, the techniques of the disclosure can be easily understood and embodied by a person of average skill in the art, and the related objects and advantages of the disclosure can be easily understood by a person of average skill in the art by referring to the contents, the claims and the accompanying drawings disclosed in the specifications. The embodiments mentioned below are used to further describe the advantages of the disclosure in details, but should not be construed as limitations of the scope of the disclosure.

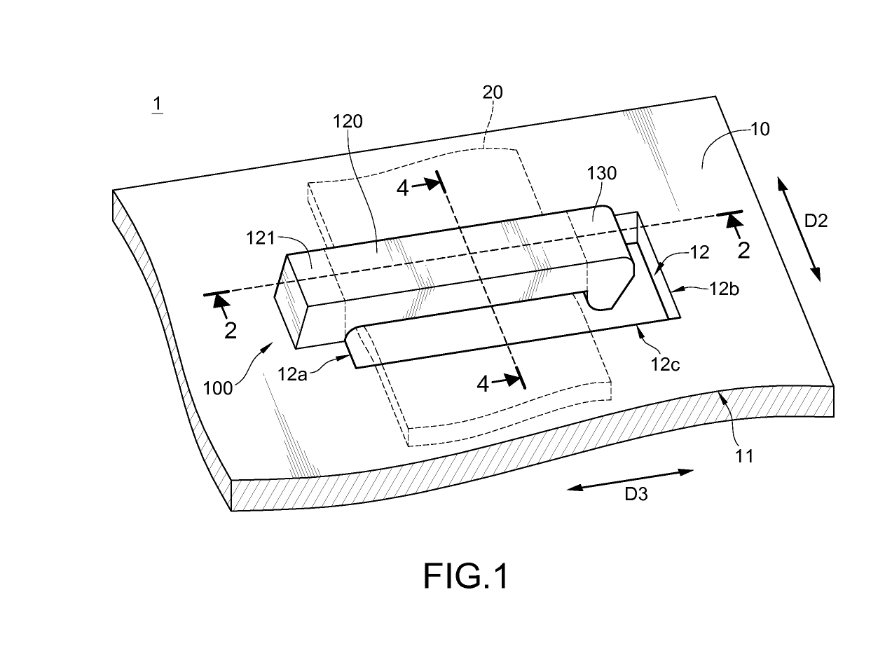

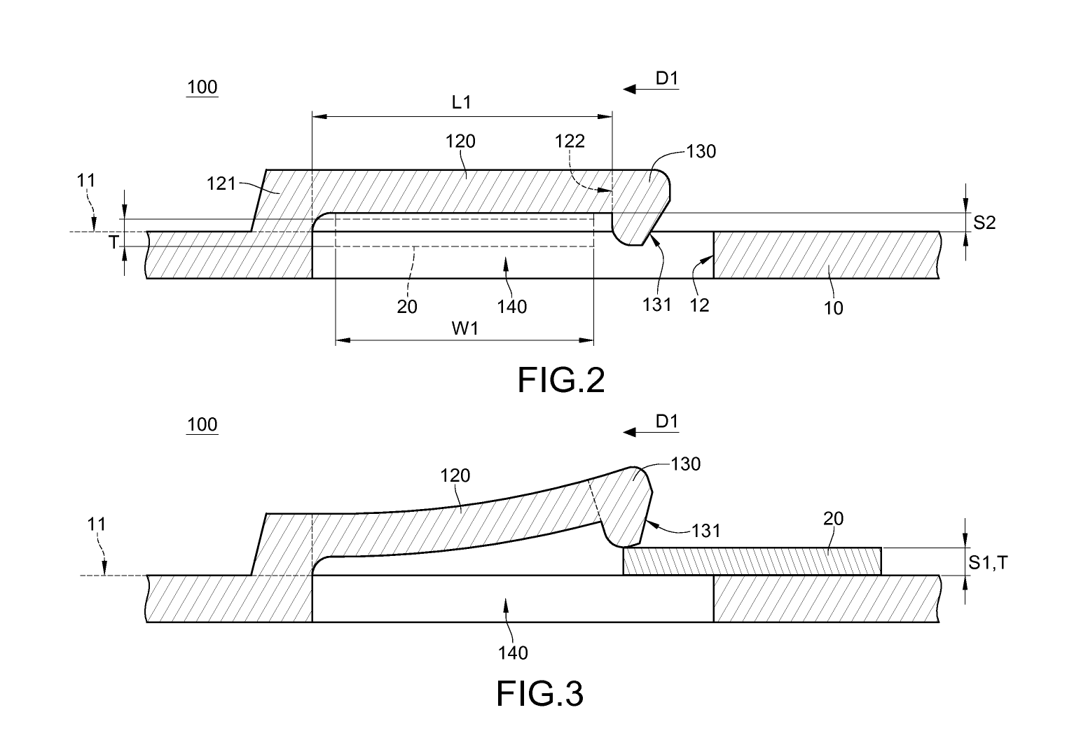

Referring to FIG. 1, which is a perspective view of an electronic device 1 of an embodiment of the disclosure. The electronic device 1 of the disclosure comprises a case 10, a wire 20 and a fixing structure 100. The case 10 has a surface 11, and an opening 12 is formed on the surface 11. The wire 20 is disposed on the surface 11. The fixing structure 100 is disposed on the surface 11 and is adjacent to the opening 12. Referring to FIG. 2, which is a front cross-sectional view of the fixing structure 100 in FIG. 1 taken along a line 2-2. The fixing structure 100 comprises a suspension arm 120 and a hook portion 130. The suspension arm 120 has an engaging end 121 and a suspending end 122. The engaging end 121 is connected to the surface 11 of the case 10, so that the suspension arm 120 is extended from the surface 11 of the case 10. The suspending end 122 is suspended at the opening 12. The hook portion 130 is extended from the suspending end 122 and reaches inside the opening 12. The wire 20 passes through between the case 10 and the suspension arm 120.

The fixing structure 100 can be, for examples, used in slim displays, laptops, tablet computes, personal digital assistants, smart phones, keyboards or other electronic devices. As shown in FIG. 2, an accommodating space 140 is formed by the suspension arm 120 and the hook portion 130 for accommodating the wire 20. The wire 20 can be, for examples, a flexible flat cable (FFC), a flexible printed circuit (FPC) board or other types of wires. Because the hook portion 130 is extended to reach inside the opening 12, the wire 20 accommodated in the accommodating space 140 will not be easily moved away from the accommodating space 140, and thereof it is not easy for the wire 20 to come off from a gap between the fixing structure 100 and the case 10. Accordingly, the purpose of fixing the wire 20 is achieved.

Referring to FIG. 2, in this embodiment, the suspension arm 120 is formed in one piece with the case 10, and is undetachably disposed on the case 10. The hook portion 130 is undetachably connected with the suspension arm 120 in one piece. The undetachable form can be achieved by injection molding to form in one piece. In this embodiment, the opening 12 passes through the case 10, such design is favorable for injection molding. In other embodiments, the opening 12 can be formed merely as an indentation on the surface 11 of the case 10, such design makes the case 10 more solid structurally.

Referring to FIG. 2, in this embodiment, along an entering direction D1 to enter into the accommodating space 140 from the hook portion 130, an inclined guiding surface 131 is disposed on a receiving surface of the hook portion 130 facing against the entering direction D1. Referring to FIG. 3, which is a front cross-sectional view of the fixing structure 100 of an embodiment of the disclosure being installed with the wire 20. When the wire 20 is guided into the accommodating space 140 from the inclined guiding surface 131 of the hook portion 130 along the entering direction D1, because the wire 20 is pressed against on the inclined guiding surface 131 along the entering direction D1, thus the hook portion 130 is lifted upward and the suspension arm 120 is bent upward. Until the hook portion 130 is lifted upward to a position that a gap S1 between the hook portion 130 and the surface 11 is equal to a thickness T of the wire 20, then a side of the wire 20 can be pressed against the hook portion 130, while another side of the wire 20 is entered into the accommodating space 140 through the gap S1. In other embodiments, the hook portion 130 can be lifted upward first by using other tools or external forces, then the wire 20 can be entered into the accommodating space 140 along the entering direction D1.

Referring to FIG. 2 again, in this embodiment, a length L1 of the suspension arm 120 is longer than a width W1 of the wire 20. After the wire 20 is accommodated into the accommodating space 140 along the entering direction D1, because the length L1 of the suspension arm 120 is longer than the width W1 of the wire 20, thus the wire 20 is no longer pressed against the hook portion 130. Therefore, the hook portion 130 will be restored downwardly to an original position of extending inside the opening 12 by the flexibility and the elasticity of the suspension arm 120. Because the hook portion 130 is extended into the opening 12, the wire 20 will not easily come off from the accommodating space 140, so that the wire 20 is fixed. Furthermore, when the wire 20 is needed to be fixed, simply move the wire 20 from a side of the fixing structure 100 disposed with the hook portion 130 into the accommodating space 140, thus it is not required to be fixed by entering from multiple sides which is more complicated.

Furthermore, as shown in FIG. 2, in this embodiment, a distance S2 between the suspension arm 120 suspended above the surface 11 is slightly smaller than the thickness T of the wire 20. Therefore, when the wire 20 is accommodated inside the accommodating space 140, the wire 20 is lightly clamped by the suspension arm 120, and thus an additional fixing force is provided for clamping the wire 20, and an effect of fixing the wire 20 is further enhanced. In other embodiments, the distance S2 the suspension arm 120 suspended above the surface 11 can be substantially equal to or slightly bigger than the thickness T of the wire 20. If the wire 20 is made of more fragile materials, it can be avoided that the wire 20 will get damaged by being overly clamped by the suspension arm 120.

Referring to FIG. 1 again, in this embodiment, the opening 12 is a rectangle with two short sides 12a and 12b. The engaging end 121 of the suspension arm 120 is disposed adjacent to the short side 12a of the two short sides 12a and 12b of the opening 12. The suspension arm 120 is extended from the surface 11 of the case 10 towards a direction away from the surface 11, and is stretched over the opening 12. The hook portion 130 is extended towards the opening 12 and reaches inside the opening 12. Even though the hook portion 130 is adjacent to the other short side 12b, but is not disposed beyond an upwardly extended range of the opening 12. A direction D3 the suspension arm 120 stretching over the opening 12 is perpendicular to an extending direction D2 of the wire 20.

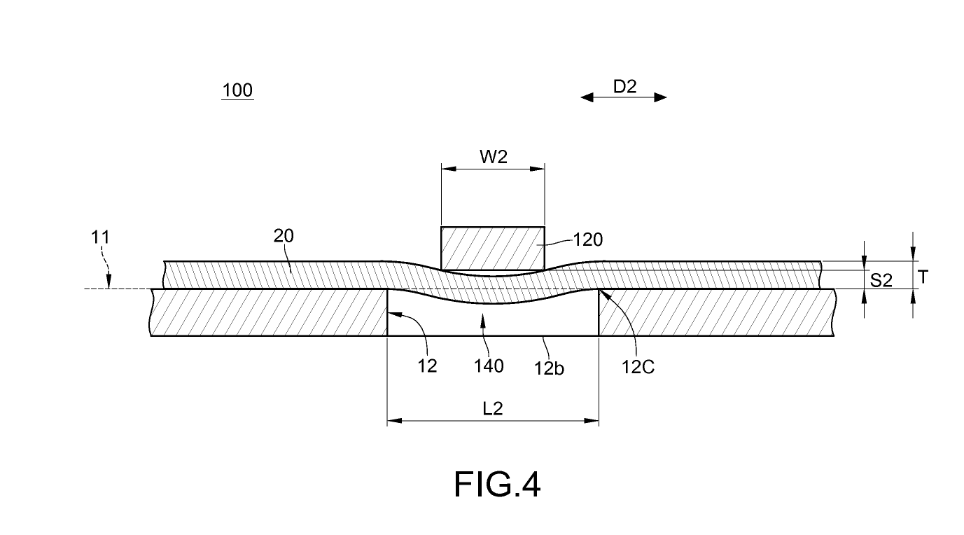

Referring to FIG. 4, which is a side cross-sectional view of the fixing structure 100 in FIG. 1 along a line 4-4 installed with the wire 20. Because a length L2 of the short side 12b of the opening 12 is bigger than a width W2 of the suspension arm 120, thus besides suspending above the opening 12, the suspension arm 120 is completely within the two opposite side of the opening 12. The rectangular opening 12 also has two long sides 12c, thus there is a gap between each of the long sides 12c and the suspension arm 120. If the distance S2 between the suspension arm 120 suspended above the surface 11 is slightly smaller than the thickness T of the wire 20, the wire 20 will be bent as a U shape in a space between the opening 12 and the suspension arm 120. Such U-shaped curvature can prevent a displacement of the wire 20 because of a tension in the extending direction D2 of the wire 20, therefore an effect of fixing the wire 20 is enhanced.

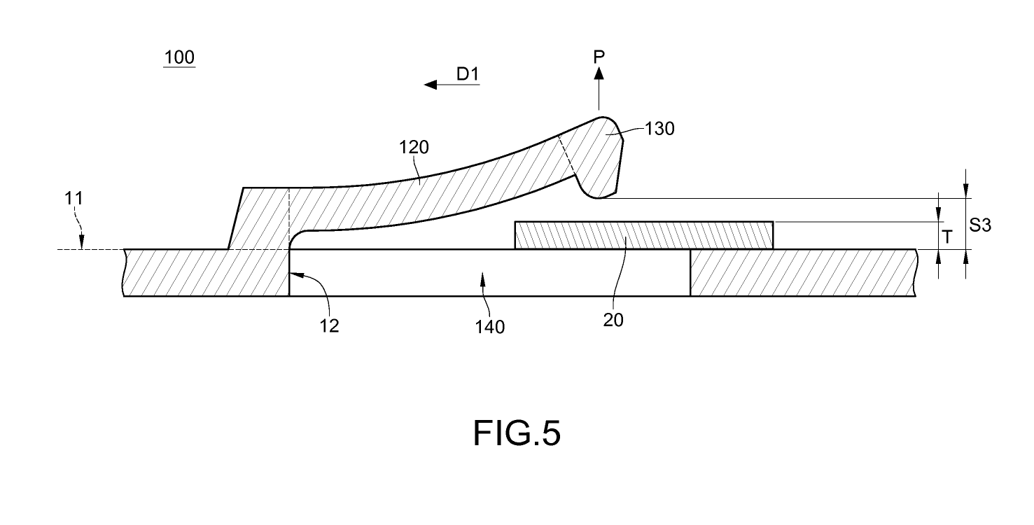

Furthermore, referring to FIG. 5, which is a front cross-sectional view of the fixing structure 100 of an embodiment of the disclosure with the wire 20 being removed. For example, when the electronic device 1 applying the fixing structure 100 needed to be maintained, sometimes it is necessary to remove the wire 20 from the accommodating space 140 of the fixing structure 100. When the wire 20 is required to be removed from its fixed position, the hook portion 130 can be slightly lifted by an external force P of manpower or tools, so that a gap S3 either bigger than or equal to the thickness T of the wire 20 is formed between the hook portion 130 and the surface 11, the wire 20 can then be withdrawn from the accommodating space 140 in a direction opposite to the entering direction D1. After that, stop applying the external force P, so that the hook portion 130 can be restored downwardly to the original position of extending inside the opening 12 by the flexibility and the elasticity of the suspension arm 120.

As a conclusion from the abovementioned, the hook portion of the fixing structure of the disclosure is extended to reach inside the opening, so the wire accommodated inside the accommodating space will not be easily removed outside the accommodating space, and thus the wire will not easily come off from the gap between the fixing structure and the case. Because of the inclined guiding surface of the hook portion, the wire can be easily assembled in the fixing structure. Furthermore, because the distance the suspension arm suspended above the surface is slightly smaller than the thickness of the wire, when the wire is accommodated inside the accommodating space, the wire is lightly clamped by the suspension arm, and therefore an effect of fixing the wire is enhanced. In addition, because the wire is bent as a U shape in a space between the opening and the suspension arm, thus the wire can be prevented from displacement due to the tension in the lengthwise direction, therefore an effect of fixing the wire is enhanced.

Note that the specifications relating to the above embodiments should be construed as exemplary rather than as limitative of the present invention, with many variations and modifications being readily attainable by a person of average skill in the art without departing from the spirit or scope thereof as defined by the appended claims and their legal equivalents.

What is claimed is:

1. A fixing structure disposed on a surface of a case, an opening being disposed on the surface of the case, the fixing structure comprising:
a suspension arm extended from the surface of the case, the suspension arm having an engaging end and a suspending end, the engaging end being connected to the surface of the case, the suspending end being suspended at the opening; and
a hook portion extended from the suspending end, and being extended to reach inside the opening.

2. The fixing structure as claimed in claim 1, wherein an accommodating space is formed by the suspension arm and the hook portion, along an entering direction to enter into the accommodating space from the hook portion, an inclined guiding surface is disposed on a receiving surface of the hook portion facing against the entering direction.

3. The fixing structure as claimed in claim 1, wherein the fixing structure is for fixing a wire extended along an extending direction, a length of the suspension arm is longer than a width of the wire, and a distance the suspension arm suspended above the surface of the case is slightly smaller than a thickness of the wire.

4. The fixing structure as claimed in claim 3, wherein the suspension arm is extended from the surface of the case towards a direction away from the case, and is stretched over the opening, the hook portion is extended towards the opening and reaches inside the opening, a direction the suspension arm stretching over the opening is perpendicular to the extending direction of the wire.

5. The fixing structure as claimed in claim 1, wherein the suspension arm is undetachably disposed on the case in one piece, the hook portion is undetachably connected with the suspension arm in one piece.

6. An electronic device, comprising:
a case having a surface, an opening is disposed on the surface;
a wire disposed on the surface and being extended along an extending direction; and
a fixing structure disposed on the surface and being adjacent to the opening, the fixing structure comprising a suspension arm and a hook portion, the suspension arm being extended from the surface and having an engaging end and a suspending end, the engaging end being connected to the surface, the suspending end being suspended at the opening, the hook portion being extended from the suspending end to reach inside the opening, the wire being passed through between the case and the suspension arm.

7. The electronic device as claimed in claim 6, wherein an accommodating space is formed by the suspension arm and the hook portion, along an entering direction to enter into the accommodating space from the hook portion, an inclined guiding surface is disposed on a receiving surface of the hook portion facing against the entering direction.

8. The electronic device as claimed in claim 6, wherein a length of the suspension arm is longer than a width of the wire, and a distance the suspension arm suspended above the surface of the case is slightly smaller than a thickness of the wire.

9. The electronic device as claimed in claim 8, wherein the suspension arm is extended from the surface of the case towards a direction away from the case, and is stretched over the opening, the hook portion is extended towards the opening and reaches inside the opening, a direction the suspension arm stretching over the opening is perpendicular to the extending direction of the wire.

10. The electronic device as claimed in claim 6, wherein the suspension arm is undetachably disposed on the case in one piece, the hook portion is undetachably connected with the suspension arm in one piece.
